(19) United States
(12) Patent Application Publication
(10) Pub. No.: US 2025/0248224 A1
(43) Pub. Date: Jul. 31, 2025

(54) DISPLAY DEVICE AND METHOD FOR MANUFACTURING THE SAME

(71) Applicant: Samsung Display Co., LTD., Yongin-si (KR)

(72) Inventors: A Rong LEE, Yongin-si (KR); Kyong Sub KIM, Yongin-si (KR)

(73) Assignee: Samsung Display Co., LTD., Yongin-si (KR)

(21) Appl. No.: 18/816,451

(22) Filed: Aug. 27, 2024

(30) Foreign Application Priority Data
Jan. 31, 2024 (KR) 10-2024-0014890

(51) Int. Cl. H10K 59/122; H10K 59/12

(52) U.S. Cl. CPC H10K 59/122; H10K 59/1201

(57) ABSTRACT

A display device according to an embodiment includes a light emitting element disposed in an emission area, and a bank surrounding the emission area, wherein the light emitting element includes a first electrode, a first intermediate layer having a first height lower than a height of the bank and surrounded by the bank, a light emitting layer having a second height higher than the first height and surrounded by the bank, a second intermediate layer having the second height and surrounded by the bank, and a second electrode, wherein a top surface of the first intermediate layer is in contact with a side surface of the bank at a first pinning point of the first height, and top surfaces of the light emitting layer and the second intermediate layer are in contact with the side surface of the bank at a second pinning point of the second height.

### CROSS-REFERENCE TO RELATED APPLICATION

This application claims priority to and benefits of Korean Patent Application No. 10-2024-0014890 under 35 U.S.C. § 119, filed on Jan. 31, 2024, in the Korean Intellectual Property Office (KIPO), the contents of which in its entirety are herein incorporated by reference.

### BACKGROUND

### 1. Technical Field

The disclosure relates to a display device and a method for manufacturing the same.

### 2. Description of the Related Art

With the advance of information-oriented society, more and more demands are placed on display devices for displaying images in various ways. Along with this trend, various types of display devices including a light emitting display device are being developed. A light emitting display device includes a pixel including a light emitting element.

### SUMMARY

Aspects of the disclosure provide a display device capable of blocking a leakage current of a pixel and improving an opening ratio, and a method for manufacturing the same.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, there is provided a display device including a light emitting element disposed in an emission area, and a bank surrounding the emission area. The light emitting element includes, a first electrode, a first intermediate layer disposed on the first electrode, having a first height lower than a height of the bank, and surrounded by the bank, a light emitting layer disposed on the first intermediate layer, having a second height higher than the first height, and surrounded by the bank, a second intermediate layer disposed on the light emitting layer, having the second height, and surrounded by the bank, and a second electrode disposed on the second intermediate layer. A top surface of the first intermediate layer is in contact with a side surface of the bank at a first pinning point of the first height, and top surfaces of the light emitting layer and the second intermediate layer are in contact with the side surface of the bank at a second pinning point of the second height.

In an embodiment, a side surface of the light emitting layer may be in contact with the side surface of the bank between the first pinning point and the second pinning point.

In an embodiment, the bank may include a lower part surrounding the first intermediate layer, and an upper part surrounding the light emitting layer and the second intermediate layer and having higher liquid repellency than the lower part.

In an embodiment, the bank may contain fluorine contained in a surface at a height higher than or equal to a third height lower than a height of a top surface of the bank.

In an embodiment, the height of the bank may be higher than or equal to the second height.

In an embodiment, the bank may cover an edge portion of the first electrode and expose a remaining area including a central portion of the first electrode, and the side surface of the bank may be inclined at an angle of about 70° or more with respect to a top surface of the first electrode.

In an embodiment, the first intermediate layer may include at least one of a hole injection layer or a hole transport layer, and the second intermediate layer may include an electron transport layer.

In an embodiment, the light emitting layer may include a quantum dot.

In an embodiment, the second electrode may be disposed on the second intermediate layer and the bank and may be entirely disposed in a display area including a plurality of emission areas including the emission area.

In an embodiment, the second electrode may have a thickness of 90 Å or less.

According to an aspect of the disclosure, there is provided a display device including a light emitting element disposed in an emission area, and a bank surrounding the emission area. The light emitting element includes, a first electrode, a first intermediate layer disposed on the first electrode, having a first height lower than a height of the bank, and surrounded by the bank, a light emitting layer disposed on the first intermediate layer, having a second height higher than the first height, and surrounded by the bank, a second intermediate layer disposed on the light emitting layer, having a height higher than or equal to the second height, and surrounded by the bank, and a second electrode disposed on the second intermediate layer. The bank includes a lower part surrounding the first intermediate layer, and an upper part surrounding the light emitting layer and the second intermediate layer and having higher liquid repellency than the lower part.

In an embodiment, the second intermediate layer may be formed to the second height.

In an embodiment, a top surface of the first intermediate layer may be in contact with a side surface of the bank at a first pinning point of the first height, and top surfaces of the light emitting layer and the second intermediate layer may be in contact with the side surface of the bank at a second pinning point of the second height.

In an embodiment, a side surface of the light emitting layer may be in contact with the side surface of the bank between the first pinning point and the second pinning point.

In an embodiment, the bank may contain fluorine contained in a surface at a height higher than or equal to a third height lower than a height of a top surface of the bank.

In an embodiment, the bank may cover an edge portion of the first electrode and expose a remaining area including a central portion of the first electrode, and a side surface of the bank may be inclined at an angle of about 70° or more with respect to a top surface of the first electrode.

In an embodiment, the first intermediate layer may include at least one of a hole injection layer or a hole transport layer, and the second intermediate layer may include an electron transport layer.

In an embodiment, the light emitting layer may include a quantum dot.

According to an aspect of the disclosure, there is provided a method for manufacturing a display device, including forming a first electrode on a substrate, forming a bank covering an edge of the first electrode, and exposing a remaining portion of the first electrode, supplying a first ink onto the exposed portion of the first electrode, and forming a first intermediate layer using a material contained in the first ink, supplying a second ink having surface energy higher than that of the first ink onto the first intermediate layer, and forming a light emitting layer using a material contained in the second ink, supplying a third ink onto the light emitting layer, and forming a second intermediate layer using a material contained in the third ink, and forming a second electrode on the second intermediate layer. A top surface of the first intermediate layer is formed to be in contact with a side surface of the bank at a first pinning point of a first height lower than a height of the bank, and a top surface of the light emitting layer is formed to be in contact with the side surface of the bank at a second pinning point of a second height higher than the first height.

In an embodiment, the bank may be formed of a material containing fluorine and may be formed to have higher liquid repellency at an upper part higher than or equal to a third height than at a lower part lower than or equal to the third height.

In accordance with the display device and the method for manufacturing the same according to embodiments, a pinning point of a first intermediate layer disposed on a first electrode of a light emitting element, and a pinning point of a light emitting layer and a second intermediate layer disposed on the first intermediate layer may be disposed at different heights.

Accordingly, the first intermediate layer and the second intermediate layer may be stably separated with the light emitting layer interposed therebetween on the side surface of the light emitting element. In accordance with embodiments, a leakage current of a pixel through the side surface of the light emitting element may be prevented or blocked. Further, the level difference formed on the top surface of the second intermediate layer may be reduced, thereby preventing disconnection of the second electrode disposed on the second intermediate layer.

In some embodiments, the taper angle of the bank surrounding the emission area where the light emitting element is disposed may be about 70° or more. In accordance with embodiments, the opening ratio of the pixel may be improved, and the high-resolution display device may be appropriately or readily manufactured.

However, effects according to the embodiments of the disclosure are not limited to those discussed above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment;

FIG. 2 is a schematic diagram of an equivalent circuit schematically illustrating a pixel according to an embodiment;

FIG. 3 is a schematic plan view showing a display area according to an embodiment;

FIG. 4 is a schematic cross-sectional view illustrating a display panel according to an embodiment;

FIG. 5 is a schematic cross-sectional view showing a light emitting element according to an embodiment;

FIG. 6 is a schematic cross-sectional view showing a light emitting element according to an embodiment; and

FIGS. 7 to 12 are schematic cross-sectional views showing a method for manufacturing the display device according to an embodiment.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Features of each of various embodiments of the disclosure may be partially or entirely combined with each other and may technically variously interwork with each other, and respective embodiments may be implemented independently of each other or may be implemented together in association with each other.

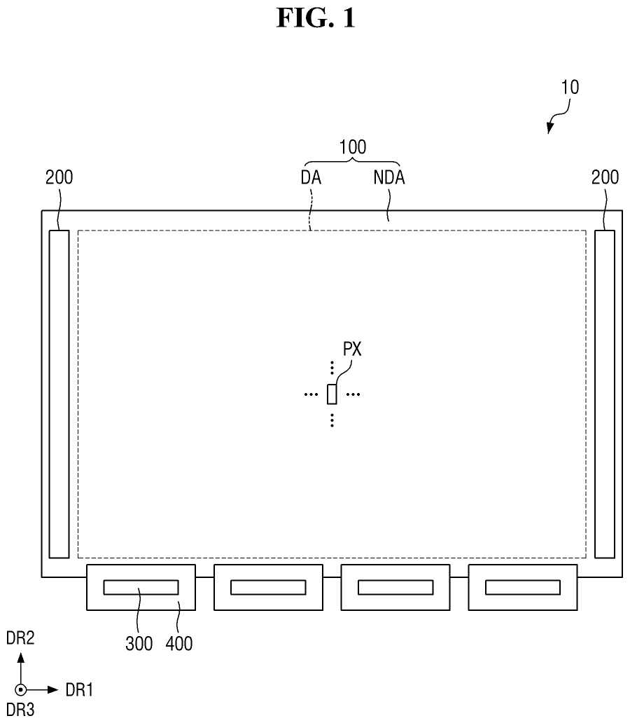

FIG. 1 is a schematic plan view illustrating a display device according to one embodiment.

Referring to FIG. 1, a display device 10 may be a device for displaying an image. The display device 10 may be applied to various electronic devices such as televisions, laptop computers, monitors, billboards, and Internet of things (IoT) devices as well as portable electronic devices such as mobile phones, smart phones, tablet personal computers (PCs), smart watches, watch phones, mobile communication terminals, electronic notebooks, e-book readers, portable multimedia players (PMPs), navigation systems, and ultra-mobile PCs (UMPCs). The display device 10 may also be applied to other electronic devices.

In an embodiment, the display device 10 may be a light emitting display device such as an organic light emitting display using an organic light emitting diode, a quantum dot light emitting display including a quantum dot light emitting layer, an inorganic light emitting display including an inorganic semiconductor, and a micro or nano light emitting display using a micro or nano light emitting diode (LED). In the following, embodiments in which the display device 10 is a quantum dot light emitting display device are described, but the type of display device 10 is not limited thereto. For example, the display device 10 according to embodiments may be an organic light emitting display device.

The display device 10 may include a display panel 100 including pixels PX, and a first driver 200 and a second driver 300 configured to supply driving signals to the pixels PX. The display device 10 may further include additional components. For example, the display device 10 may further include a power supply unit for supplying power voltages to the pixels PX, the first driver 200, and the second driver 300, and a timing controller for controlling the operations of the first driver 200 and the second driver 300.

The display panel 100 may include a display area DA and a non-display area NDA. The display area DA may be an area where the pixels PX are arranged, and an image may be displayed in the display area DA by the pixels PX. The non-display area NDA may be an area other than the display area DA, and an image may not be displayed in the non-display area NDA. In an embodiment, the non-display area NDA may be positioned around the display area DA and may surround the display area DA.

A first direction DR1, a second direction DR2, and a third direction DR3 are defined in FIG. 1. The first direction DR1 and the second direction DR2 may be perpendicular to each other, the first direction DR1 and the third direction DR3 may be perpendicular to each other, and the second direction DR2 and the third direction DR3 may be perpendicular to each other. In an embodiment, the first direction DR1, the second direction DR2, and the third direction DR3 may be the horizontal direction, the vertical direction, and the thickness direction (or the height direction) of the display panel 100, respectively.

In an embodiment, the display panel 100 may have a rectangular shape in a plan view. For example, the display panel 100 may include two first sides (e.g., horizontal sides) extending in the first direction DR1 and two second sides (e.g., vertical sides) extending in the second direction DR2 intersecting the first direction DR1. A corner where the first side and the second side of the display panel 100 meet each other may have a right angle. However, the disclosure is not limited thereto, and the corner may have a curved surface. In an embodiment, the first side may be longer than the second side, but embodiments are not limited thereto.

The planar shape of the display panel 100 is not limited to the shape, and may be a circular shape or other shapes. Further, although it is illustrated in FIG. 1 that the display panel 100 has a flat shape, embodiments are not limited thereto. The display panel 100 may be rigid or flexible.

At least one surface of the display panel 100 may be a display surface on which an image is displayed. For example, the display panel 100 may display an image on one surface (e.g., a top surface) thereof, or may display an image on at least two surfaces (e.g., a top surface and a bottom surface, or a top surface and at least one side surface) thereof.

The pixels PX may emit light with a luminance corresponding to each of driving signals supplied from the first driver 200 and the second driver 300. Accordingly, an image may be displayed in the display area DA.

In embodiments, each pixel PX may be a self-light emitting pixel including at least one light emitting element. In an embodiment, the pixel PX may include a quantum dot light emitting element (e.g., a quantum dot light emitting diode) including a quantum dot light emitting layer. However, the type of the light emitting element provided in the pixel PX is not limited to the quantum dot light emitting element. For example, the pixel PX may include an organic light emitting element (e.g., an organic light emitting diode).

The pixel PX may further include a pixel circuit (also referred to as “pixel driver”) for controlling a driving current flowing through the light emitting element. In this case, the pixel PX may further include at least one circuit element (e.g., transistors including a switching transistor and a driving transistor, and at least one capacitor) constituting a pixel circuit.

The first driver 200 and the second driver 300 may generate driving signals for controlling the operation timing and the emission luminance of the pixels PX, and may supply the driving signals to the pixels PX. For example, the first driver 200 may be a gate driver including a scan driver, and may supply respective gate signals (e.g., gate signals including scan signals) to the pixels PX. The second driver 300 may be a source driver including a data driver, and may supply data signals to the pixels PX.

In an embodiment, at least one of the first driver 200 or the second driver 300, or a part of the at least one driver may be embedded in the display panel 100. For example, the first driver 200 (or a part of the first driver 200) may be disposed or formed in the non-display area NDA of the display panel 100.

Although FIG. 1 illustrates the display device 10 in which the first driver 200 is disposed in the non-display area NDA located on both sides of the display area DA, the location of the first driver 200 is not limited thereto. For example, the first driver 200 may be disposed only on one side (e.g., a left side or a right side) of the display area DA. In another embodiment, a part (e.g., some of the circuit elements constituting the first driver 200) of the first driver 200 may be disposed in the non-display area NDA, and another part (e.g., the other circuit elements constituting the first driver 200) of the first driver 200 may be disposed in a non-emission area (e.g., the area between the emission areas of the pixels PX) in the display area DA. In another embodiment, the first driver 200 may be disposed or formed outside the display panel 100 to be electrically connected to the display panel 100.

In an embodiment, the other one of the first driver 200 and the second driver 300, or a part of the other driver may be disposed or formed outside the display panel 100 to be electrically connected to the display panel 100. For example, the second driver 300 (or a part of the second driver 300) may be disposed on a circuit board 400 (e.g., a flexible circuit board) implemented as integrated circuit chips and electrically connected to the pixels PX of the display panel 100.

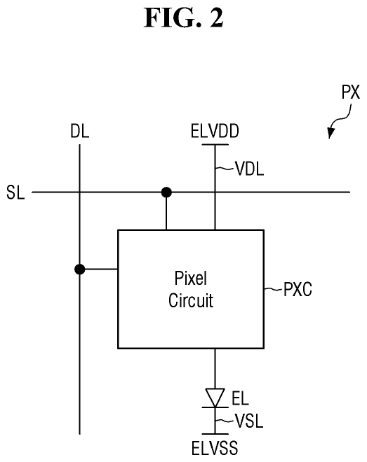

FIG. 2 is a diagram of an equivalent circuit schematically illustrating a pixel according to an embodiment.

Referring to FIGS. 1 and 2, each of the pixels PX may include a light emitting element EL connected to a first power line VDL to which a first power voltage ELVDD is applied and a second power line VSL to which a second power voltage ELVSS is applied. The first power voltage ELVDD may be a high-potential pixel voltage, and the second power voltage ELVSS may be a low-potential pixel voltage.

In an embodiment, each pixel PX may further include a pixel circuit PXC connected to the light emitting element EL. The pixel circuit PXC may be connected between the first power line VDL and the light emitting element EL. Depending on the structure and/or type of the pixel circuit PXC, the pixel circuit PXC may be connected between the light emitting element EL and the second power line VSL.

The pixel circuit PXC may be further connected to at least one scan line SL to which at least one scan signal is applied and a data line DL to which a data signal is applied. Depending on the structure, type, and/or driving method of the pixel circuit PXC, the pixel circuit PXC may be further connected to at least one other power line supplied with an initialization power voltage and/or a bias voltage or the like, and/or an emission control line or the like supplied with an emission control signal.

The pixel circuit PXC may control the driving current supplied to the light emitting element EL to correspond to the driving signals supplied to the pixel PX. For example, the pixel circuit PXC may control the size and/or supply timing of the driving current supplied to the light emitting element EL to correspond to driving signals including scan signals, data signals, or the like.

The pixel circuit PXC may include circuit elements for controlling the driving current flowing through the pixel PX to correspond to driving signals. For example, the pixel circuit PXC may include circuit elements including a switching transistor for transmitting the data signal supplied to the data line DL, to the interior of the pixel during the period for which the scan signal of a gate-on voltage is supplied to the scan line SL, a capacitor for storing the data signal, and a driving transistor for generating a driving current corresponding to the data signal. In an embodiment, the pixel circuit PXC may further include at least one other switching transistor for compensating for luminance deviation or the like of the pixels PX.

The light emitting element EL may be connected between the pixel circuit PXC and the second power line VSL. The light emitting element EL may emit light corresponding to the driving current supplied from the pixel circuit PXC. For example, during the period for which a driving current is supplied from the pixel circuit PXC, the light emitting element EL may emit light with a luminance corresponding to the magnitude of the driving current.

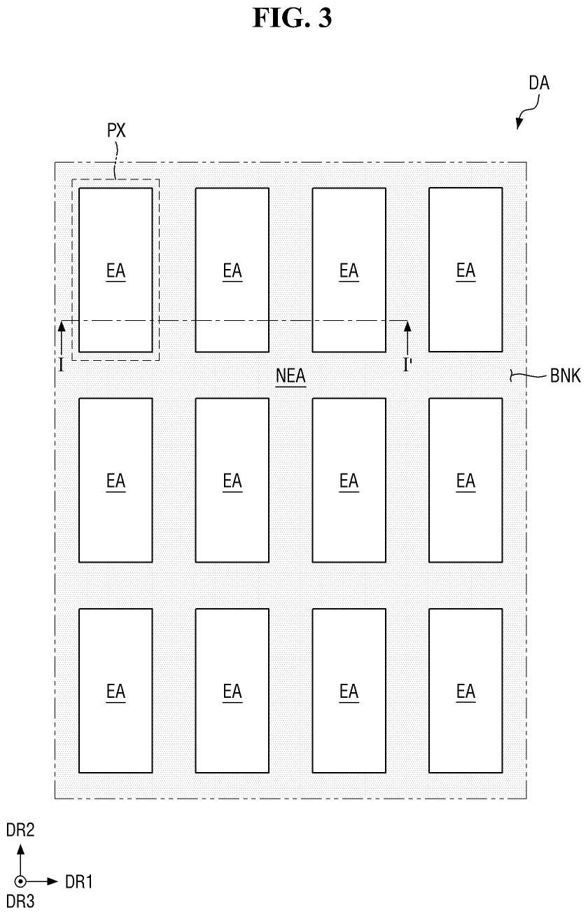

FIG. 3 is a schematic plan view illustrating a display area according to an embodiment. For example, FIG. 3 schematically illustrates a part of the display area DA shown in FIG. 1.

Referring to FIG. 3, the pixels PX including respective emission areas EA may be disposed in the display area DA. For example, each pixel PX may include the emission area EA and a peripheral area positioned around the emission area EA.

Although it is illustrated in FIG. 3 that the emission areas EA of the pixels PX have the same shape and size, embodiments are not limited thereto. For example, the pixels PX may be divided into groups (e.g., first color pixels, second color pixels, and third color pixels), and the pixels PX may include the emission areas EA of different sizes and/or shapes for different groups. Further, although FIG. 3 illustrates an embodiment in which the emission areas EA of the pixels PX have a rectangular shape and are arranged in the display area DA in a matrix form in the first direction DR1 and the second direction DR2, embodiments are not limited thereto. For example, the shape, size, ratio, and/or arrangement structure of the pixels PX may variously change depending on embodiments.

The emission area EA, which is an area where the light emitting element of the pixel PX is disposed, may be, e.g., an area where the light emitting layer of the light emitting element is positioned. Light generated by the light emitting element may be emitted from the emission area EA.

A bank BNK (also referred to as “pixel defining layer”) may be disposed at the edge portion of the emission area EA and/or around the emission area EA. For example, the emission area EA may be surrounded by the bank BNK. The bank BNK may be opened in the emission area EA.

In the pixel area where each pixel PX is disposed, the remaining area except the emission area EA may be a peripheral area. The peripheral area may be an area immediately adjacent to the emission area EA of the corresponding pixel PX, and may belong to the non-emission area NEA. For example, the display area DA may include the emission areas EA of the pixels PX and the non-emission area NEA surrounding the emission areas EA. The emission areas EA of the pixels PX may be spaced apart from each other with a part of the non-emission area NEA interposed therebetween.

Each pixel area may include a light emitting element area (e.g., an area corresponding to the emission area EA of the pixel PX, where the light emitting layer of the light emitting element or the opening of the bank BNK is positioned) where a light emitting element is disposed. In an embodiment, each pixel area may further include a pixel circuit area where circuit elements of the pixel circuit PXC are disposed. The pixel circuit area and the emission area EA of each pixel PX may or may not overlap each other in the third direction DR3. The bank BNK may be further disposed in the display area DA. The bank BNK may be disposed in the non-emission area NEA, and may surround the emission areas EA of the pixels PX.

The bank BNK may be opened to expose the emission areas EA of the pixels PX. For example, the bank BNK may include openings corresponding to the emission areas EA of the pixels PX, and may be positioned between the emission areas EA and/or in a peripheral area therearound. In an embodiment, a part of the bank BNK may be positioned at the edge of the emission area EA.

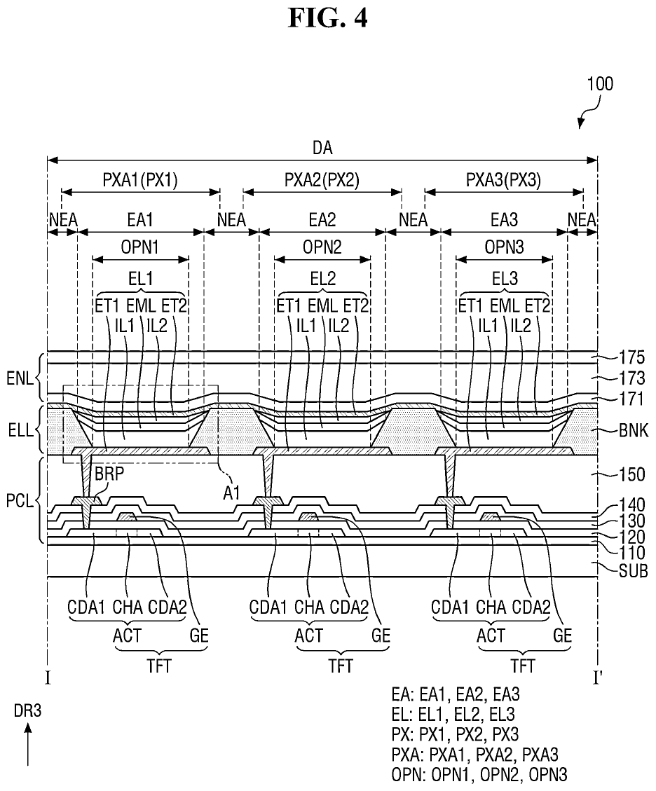

FIG. 4 is a schematic cross-sectional view illustrating a display panel according to an embodiment. For example, FIG. 4 illustrates a cross section of a part of the display panel 100, and illustrates an embodiment for the cross section of the display area DA corresponding to line I-I′ of FIG. 3.

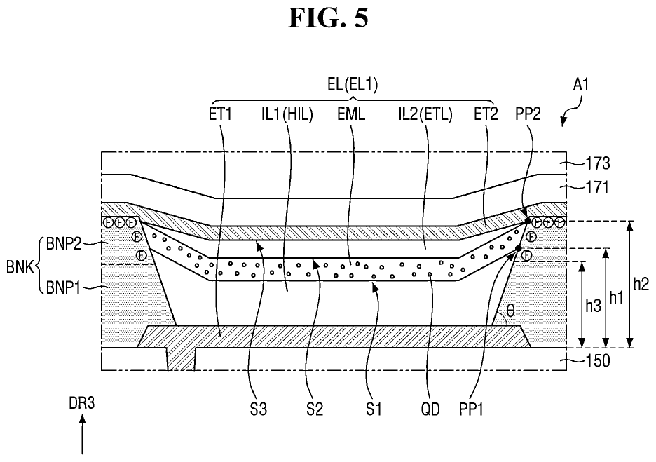

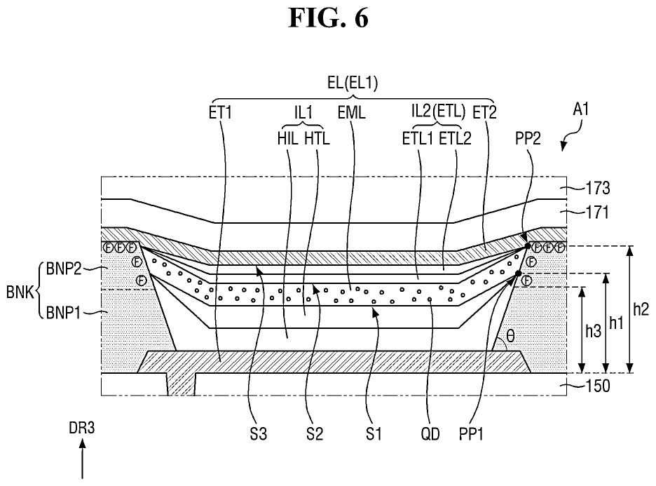

FIG. 5 is a schematic cross-sectional view illustrating a light emitting element according to an embodiment. FIG. 6 is a schematic cross-sectional view illustrating a light emitting element according to an embodiment. For example, FIGS. 5 and 6 illustrate different embodiments for the cross section of the light emitting element EL (e.g., a first light emitting element EL1) corresponding to area Al of FIG. 4. In an embodiment, the light emitting elements EL provided in the pixels PX may have structures that are substantially similar or identical to each other.

Referring to FIGS. 4 to 6, the display panel 100 may include a substrate SUB, and a light emitting element layer ELL and an encapsulation layer ENL that are sequentially disposed on the substrate SUB. In an embodiment, the display panel 100 may further include a panel circuit layer PCL disposed between the substrate SUB and the light emitting element layer ELL. The location of the panel circuit layer PCL or the like may vary depending on embodiments.

In an embodiment, the display panel 100 (or the display device 10) may further include additional components. For example, the display panel 100 may further include a protective layer (e.g., a window or a protective film) disposed on the encapsulation layer ENL, and an optical filter (e.g., a color filter layer) disposed above or under the encapsulation layer ENL. Each of the protective layer and the optical filter may be integral with the display panel 100, or may be manufactured separately from the display panel 100 and disposed on the display panel 100.

The substrate SUB, which is a base member (or a base layer) of the display panel 100, may be rigid or flexible. The substrate SUB may be at least one of a glass substrate, a quartz substrate, a glass ceramic substrate, a film substrate containing a polymer organic material, and a plastic substrate, but is not limited thereto.

The display area DA and the non-display area NDA may be defined on the substrate SUB. The display area DA may include the emission areas EA of the pixels PX and the non-emission area NEA surrounding the emission areas EA.

The emission area EA, which is an area where the light emitting element EL of each pixel PX is disposed, may be an area where the pixel PX emits light by the light emitting element EL. For example, the emission area EA, which is an area where a light emitting layer EML of the light emitting element EL provided in each pixel PX is disposed, may be an area where the light generated by the light emitting element EL is emitted. Although FIG. 4 illustrates the emission area EA with respect to the bottom surface of the light emitting layer EML, an effective emission area may vary depending on the structure or the emission type of the light emitting element EL and the pixel PX including the same.

The light emitting layer EML of the light emitting element EL may be disposed on a part of a first electrode ET1 exposed by an opening OPN of the bank BNK, and may have a size and/or shape corresponding to the opening OPN of the bank BNK. Accordingly, the emission area EA may have a size and/or shape corresponding to the opening OPN of the bank BNK.

A pixel area PXA, which is an area where each pixel PX is disposed, may include the emission area EA where the light emitting element EL of each pixel PX is disposed. In an embodiment, the pixel area PXA may further include the pixel circuit area in which the pixel circuit PXC of each pixel PX is disposed. In an embodiment, at least a part of the pixel circuit area may overlap the emission area EA of the corresponding pixel PX.

A panel circuit layer PCL (for example, a pixel circuit layer or a thin film transistor layer) may be disposed on the substrate SUB. The panel circuit layer PCL may include a barrier layer 110 (or a buffer layer), and circuit elements (e.g., transistors and a capacitor constituting the pixel circuit PXC of each pixel PX) and/or wires disposed on the barrier layer 110. FIG. 4 illustrates, as an example of elements that may be disposed in the panel circuit layer PCL, a transistor (e.g., a thin film transistor) TFT disposed in the pixel area PXA of each pixel PX and electrically connected to the light emitting element EL of the corresponding pixel PX.

The barrier layer 110 may be disposed on the substrate SUB. The barrier layer 110 may include an inorganic insulating material including, for example, silicon nitride, silicon oxide, silicon oxynitride, or the like, or another insulating material.

An active layer ACT of each of the transistors TFT may be disposed on the barrier layer 110. The active layer ACT may include, for example, polycrystalline silicon, monocrystalline silicon, low-temperature polycrystalline silicon, amorphous silicon, an oxide semiconductor, or other semiconductor materials.

The active layer ACT of the transistor TFT may include a channel area CHA, a first conductive area CDA1, and a second conductive area CDA2. The first conductive area CDA1 and the second conductive area CDA2 may be spaced apart from each other with the channel area CHA interposed therebetween.

The channel area CHA may overlap a gate electrode GE. At least a part of each of the first conductive area CDA1 and the second conductive area CDA2 may not overlap the gate electrode GE.

One of the first conductive area CDA1 and the second conductive area CDA2 may be a source region, and the other one may be a drain region. In an embodiment, one of the first conductive area CDA1 and the second conductive area CDA2 may function as a source electrode, and the other one may function as a drain electrode. In another embodiment, the transistor TFT may further include a separate source electrode and/or drain electrode respectively electrically connected to the first conductive area CDA1 or the second conductive area CDA2.

In an embodiment, a light blocking pattern may be disposed under at least one transistor TFT among the transistors TFT provided in each pixel PX. For example, the panel circuit layer PCL may further include at least one light blocking pattern disposed between the substrate SUB and the first barrier layer 110 and overlapping the active layer ACT of the at least one transistor TFT.

A first insulating layer 120 (e.g., a gate insulating layer) may be disposed on the active layers ACT of the transistors TFT. In an embodiment, the first insulating layer 120 may include at least one inorganic insulating layer including an inorganic insulating material.

The gate electrode GE of each of the transistors TFT may be disposed on the first insulating layer 120. In an embodiment, the gate electrode GE may include at least one of molybdenum (Mo), aluminum (Al), chromium (Cr), gold (Au), titanium (Ti), nickel (Ni), neodymium (Nd), and copper (Cu), or an alloy thereof. The gate electrode GE may also include other conductive materials. In an embodiment, at least one wire and/or a first electrode of a capacitor provided in each pixel PX may be further disposed on the first insulating layer 120.

A second insulating layer 130 (for example, a first interlayer insulating layer) may be disposed on the gate electrodes GE of the transistors TFT. In an embodiment, the second insulating layer 130 may include at least one inorganic insulating layer including an inorganic insulating material. In an embodiment, at least one wire and/or a second electrode of a capacitor provided in the pixel PX may be further disposed on the second insulating layer 130. In an embodiment, the source electrode and/or the drain electrode of at least one transistor TFT may be further disposed on the second insulating layer 130.

A third insulating layer 140 (for example, a second interlayer insulating layer) may be disposed on the second insulating layer 130, the second electrode of the capacitor, and/or at least one wire. In an embodiment, the third insulating layer 140 may include at least one inorganic insulating layer including an inorganic insulating material. In an embodiment, the panel circuit layer PCL may not include the third insulating layer 140.

Connection electrodes BRP may be disposed on the third insulating layer 140. In case that the panel circuit layer PCL does not include the third insulating layer 140, the connection electrodes BRP and/or the second electrode of the capacitor may be disposed on the second insulating layer 130.

The connection electrodes BRP may be connected to the first conductive areas CDA1 of the transistors TFT through respective contact holes penetrating the first insulating layer 120, the second insulating layer 130, and the third insulating layer 140. The connection electrodes BRP may include at least one of molybdenum (Mo), aluminum (Al), chromium (Cr), gold (Au), titanium (Ti), nickel (Ni), neodymium (Nd), and copper (Cu), or an alloy thereof, or another conductive material. The connection electrodes BRP may be formed as a single layer or multiple layers.

A fourth insulating layer 150 (e.g., a planarization layer) may be disposed on the connection electrodes BRP. In an embodiment, the fourth insulating layer 150 may include an organic insulating layer containing acryl resin, epoxy resin, phenolic resin, polyamide resin, polyimide resin, or other organic insulating materials. The fourth insulating layer 150 may reduce the level difference of the panel circuit layer PCL caused by the transistors TFT or the like. For example, the top surface of the fourth insulating layer 150 may be substantially flat.

The light emitting element layer ELL may be disposed on the fourth insulating layer 150. The light emitting element layer ELL may include the light emitting elements EL of the pixels PX and the bank BNK surrounding the light emitting elements EL. In an embodiment, the light emitting element layer ELL may further include additional components. For example, the light emitting element layer ELL may further include a light blocking layer (e.g., black matrix) or a reflective layer disposed around the emission area EA.

The light emitting element EL may include the first electrode ET1, the light emitting layer EML, and a second electrode ET2. In an embodiment, the first electrode ET1 may be a pixel electrode individually formed for each pixel area PXA, and the second electrode ET2 may be a common electrode commonly formed for the pixel areas PXA. In an embodiment, the second electrode ET2 may be formed entirely in the display area DA including the pixel areas PXA.

One of the first electrode ET1 and the second electrode ET2 may be an anode electrode, and the other one may be a cathode electrode. For example, the first electrode ET1 may be an anode electrode, and the second electrode ET2 may be a cathode electrode.

The light emitting element EL may further include a first intermediate layer IL1 interposed between the first electrode ET1 and the light emitting layer EML, and a second intermediate layer IL2 interposed between the light emitting layer EML and the second electrode ET2. One of the first intermediate layer IL1 and the second intermediate layer IL2 may be a layer for smooth injection and/or transport of holes, and the other one of the first intermediate layer IL1 and the second intermediate layer IL2 may be a layer for smooth injection and/or transport of electrons. In an embodiment, the first intermediate layer IL1 may include at least one of a hole injection layer HIL and a hole transport layer HTL, and the second intermediate layer IL2 may include at least one electron transport layer ETL.

The first electrode ET1 may be disposed in each pixel area PXA, and may be disposed on the panel circuit layer PCL (or the substrate SUB). For example, the first electrode ET1 of the light emitting element EL (hereinafter, referred to as “first light emitting element EL1”) provided in a first pixel PX1 may be disposed in a first pixel area PXA1 where the first pixel PX1 is disposed, and may be disposed on the fourth insulating layer 150. The first electrode ET1 of the light emitting element EL (hereinafter, referred to as “second light emitting element EL2”) provided in a second pixel PX2 may be disposed in a second pixel area PXA2 where the second pixel PX2 is disposed, and may be disposed on the fourth insulating layer 150. The first electrode ET1 of the light emitting element EL (hereinafter, referred to as “third light emitting element EL3”) provided in a third pixel PX3 may be disposed in a third pixel area PXA3 where the third pixel PX3 is disposed, and may be disposed on the fourth insulating layer 150. The first electrode ET1 may be disposed in the emission area EA of each pixel PX.

For example, the first electrode ET1 of the first light emitting element EL1 may be disposed in the emission area EA (hereinafter, referred to as “first emission area EA1”) of the first pixel PX1. The first electrode ET1 of the second light emitting element EL2 may be disposed in the emission area EA (hereinafter, referred to as “second emission area EA2”) of the second pixel PX2. The first electrode ET1 of the third light emitting element EL3 may be disposed in the emission area EA (hereinafter, referred to as “third emission area EA3”) of the third pixel PX3.

In an embodiment, a part of the first electrode ET1 may be disposed at the edge portion of the emission area EA or in the non-emission area NEA, and may be covered with the bank BNK. For example, the edge portion of the first electrode ET1 may be disposed in the non-emission area NEA, and may be covered with the bank BNK.

The first electrode ET1 may be connected to the connection electrode BRP and/or the circuit elements provided in each pixel PX. For example, the first electrode ET1 may be electrically connected to the transistor TFT constituting the pixel circuit PXC of the corresponding pixel PX through the connection electrode BRP of each pixel PX. In another embodiment, each pixel PX may not include the connection electrode BRP, and the first electrode ET1 may be directly connected to the transistor TFT through at least one contact hole.

In an embodiment, the first electrode ET1 may be a reflective electrode. For example, the first electrode ET1 may include a reflective electrode layer including at least one of aluminum (Al), molybdenum (Mo), titanium (Ti), copper (Cu), silver (Ag), magnesium (Mg), platinum (Pt), palladium (Pd), gold (Au), nickel (Ni), neodymium (Nd), iridium (Ir), and chromium (Cr), or another reflective conductive material.

In an embodiment, the first electrode ET1 may have a multi-layer structure including the reflective electrode layer. For example, the first electrode ET1 may include the reflective electrode layer, and a conductive oxide layer formed on the reflective electrode layer. In an embodiment, the conductive oxide layer may be, e.g., indium-tin-oxide (ITO), indium-zinc-oxide (IZO), indium-tin-zinc-oxide (ITZO), zinc oxide (ZnO), indium oxide (In₂O₃), indium-gallium-oxide (IGO), or aluminum-zinc-oxide (AZO), but is not limited thereto. In an embodiment, the first electrode ET1 may have a multi-layer structure such as ITO/Mg, ITO/MgF, ITO/Ag, and ITO/Ag/ITO, but is not limited thereto.

The bank BNK may be disposed on the first electrodes ET1 of the light emitting elements EL. For example, the bank BNK may cover or overlap the edge portion of each of the first electrodes ET1, and may expose the remaining area including the central portion of each of the first electrodes ET1.

The bank BNK may be disposed in the non-emission area NEA, and may surround each emission area EA. The bank BNK may or may not overlap a part (e.g., the edge portion) of the emission area EA.

The bank BNK may surround the light emitting element EL disposed in each emission area EA. For example, the bank BNK may include the openings OPN exposing most of the top surface thereof including the central portion of the first electrode ET1 disposed in each emission area EA, and may surround the first intermediate layer IL1, the light emitting layer EML, and the second intermediate layer IL2 of the light emitting element EL.

For example, the bank BNK may include a first opening OPN1 exposing the first electrode ET1 of the first light emitting element EL1, a second opening OPN2 exposing the first electrode ET1 of the second light emitting element EL2, and a third opening OPN3 exposing the first electrode ET1 of the third light emitting element EL3. The bank BNK may surround the first intermediate layer IL1, the light emitting layer EML, and the second intermediate layer IL2 of the first light emitting element EL1 disposed in the first opening OPN1, the first intermediate layer IL1, the light emitting layer EML, and the second intermediate layer IL2 of the second light emitting element EL2 disposed in the second opening OPN2, and the first intermediate layer IL1, the light emitting layer EML, and the second intermediate layer IL2 of the third light emitting element EL3 disposed in the third opening OPN3.

Each pixel PX may include the emission area EA corresponding to the opening OPN of the bank BNK. For example, the first pixel PX1 may include the first emission area EA1 having a size and a shape corresponding to the first opening OPN1 of the bank BNK. The second pixel PX2 may include the second emission area EA2 having a size and a shape corresponding to the second opening OPN2 of the bank BNK. The third pixel PX3 may include the third emission area EA3 having a size and a shape corresponding to the third opening OPN3 of the bank BNK.

Light generated by each light emitting element EL may be emitted from each emission area EA. In an embodiment, when the first electrode ET1 of the light emitting element EL includes the reflective electrode layer and the second electrode ET2 thereof includes a transparent electrode layer or a translucent electrode layer, the light emitted from the light emitting layer EML of the light emitting element EL may pass through the second electrode ET2 and be emitted to the position above the light emitting layer EML. For example, light emitted from the light emitting layer EML may be emitted in the third direction DR3 and pass through the top surface of the display panel 100.

In an embodiment, the bank BNK may include an organic insulating material selected from the group consisting of acrylic resin, epoxy resin, phenolic resin, polyamide resin, polyimide resin, unsaturated polyester resin, polyphenylene ether resin, polyphenylenesulfide resin, and benzocyclobutene (BCB). As another example, the bank BNK may include an inorganic material such as silicon nitride. The material of the bank BNK may vary according to embodiments. The bank BNK may have a single-layer structure or a multi-layer structure.

In an embodiment, the bank BNK may have a taper angle θ of about 70° or more. For example, the side surface of the bank BNK may be formed as an inclined surface inclined at a taper angle θ of about 70° or more with respect to the top surface of each of the first electrodes ET1. As the taper angle θ of the bank BNK increases, the size of each of the openings OPN may increase. Accordingly, the light emitting area (e.g., the size of the emission area EA) of the pixel PX may be improved or secured.

In embodiments, at least a part of the bank BNK including the top surface and a part of the side surface may have liquid repellency (or a hydrophobic property). For example, the bank BNK may be formed of a material containing fluorine (F), and may be formed to have higher liquid repellency at an upper part BNP2 than at a lower part BNP1.

The lower part BNP1 of the bank BNK may mainly (or generally) surround the first intermediate layer IL1. For example, the lower part BNP1 of the bank BNK may surround the first intermediate layer IL1 (or at least a part of the first intermediate layer IL1).

The upper part BNP2 of the bank BNK may mainly surround the light emitting layer EML and the second intermediate layer IL2. For example, the upper part BNP2 of the bank BNK may surround the light emitting layer EML (or a part of the light emitting layer EML) and the second intermediate layer IL2 (or a part of the second intermediate layer IL2). In an embodiment, the upper part BNP2 of the bank BNK may further surround a part of the first intermediate layer IL1 (e.g., the upper part of the first intermediate layer IL1 located at a height higher than or equal to a third height h3).

In an embodiment, the bank BNK may be formed of a material containing fluorine (F), and may include fluorine (F) contained in a surface thereof at a height higher than or equal to the third height h3 lower than the height (e.g., the height of the top surface of the bank BNK) of the bank BNK. For example, the bank BNK may include the lower part BNP1 with a height lower than or equal to the third height h3 belonging to the intermediate height of the bank BNK and the upper part BNP2 with a height higher than or equal to the third height h3, and may include fluorine (F) contained in the surface at the upper part BNP2. For example, the bank BNK may include fluorine (F) contained in the surface at the top surface and the side surface with a height higher than or equal to the third height h3, and may exhibit high liquid repellency. The third height h3 may be a height with respect to the bottom surface (or the top surface of the fourth insulating layer 150) of the bank BNK, but is not limited thereto. For example, the third height h3 may be defined with respect to the top surface of the first electrode ET1.

In describing embodiments, the third height h3 is merely presented as an example of a standard for dividing the lower part BNP1 and the upper part BNP2 of the bank BNK, and the standard for dividing the lower part BNP1 and the upper part BNP2 of the bank BNK is not limited to a specific height or whether or not fluorine (F) is contained. For example, the bank BNK may be divided into the lower part BNP1 and the upper part BNP2 with respect to a portion mainly surrounding the first intermediate layer IL1 and the remaining portion (e.g., a portion mainly surrounding the light emitting layer EML and the second intermediate layer IL2).

Further, in describing embodiments, it has been described that the surface of the bank BNK contains fluorine (F) at the upper part BNP2 with a height higher than or equal to the third height h3, but the surface of the bank BNK may contain a small amount of fluorine (F) even at the lower part BNP1 with a height lower than or equal to the third height h3. For example, the bank BNK may contain fluorine (F) with a value lower than or equal to the reference value on at least a part of the side surface with a height lower than or equal to the third height h3, and may contain fluorine (F) with a value higher than or equal to the reference value on the side surface and the top surface with a height higher than or equal to the third height h3. Further, on the side surface of the bank BNK, the content (or concentration) of fluorine (F) may gradually change depending on the height or the like.

Although FIGS. 5 and 6 illustrate embodiments in which the third height h3 is lower than a first height h1 (e.g., a height at which a first pinning point PP1 of the first intermediate layer IL1 is positioned), but embodiments are not limited thereto. For example, the third height h3 and the first height h1 may be substantially equal to each other or may be close to each other. Further, the third height h3 may be higher than or equal to the first height h1, or may be lower than or equal to the first height h1.

The first intermediate layer IL1, the light emitting layer EML, and the second intermediate layer IL2 of the light emitting element EL may be sequentially disposed on the first electrode ET1 of the light emitting element EL exposed by each opening OPN of the bank BNK. The first intermediate layer IL1, the light emitting layer EML, and the second intermediate layer IL2 of the light emitting element EL may be surrounded by the bank BNK. In an embodiment, the first intermediate layer IL1, the light emitting layer EML, and the second intermediate layer IL2 may be disposed or formed at a height lower than or equal to the height of the bank BNK. For example, the pinning point of the first intermediate layer IL1, the light emitting layer EML, and the second intermediate layer IL2 of the light emitting element EL may be positioned at a height lower than or equal to the height of the bank BNK, and may be positioned on the side surface of the bank BNK.

In embodiments, at least one of the taper angle θ or the liquid repellency (or the portion where the bank BNK has liquid repellency) of the bank BNK may be adjusted such that the first pinning point PP1 where the first intermediate layer IL1 meets the side surface of the bank BNK and a second pinning point PP2 where the light emitting layer EML and/or the second intermediate layer IL2 meets the side surface of the bank BNK are separated from each other and positioned at different heights. For example, the bank BNK may be formed such that the bank BNK has a taper angle θ of about 70° or more, and the surface of the bank BNK has liquid repellency (e.g., liquid repellency with a value higher than or equal to the reference value) from the third height h3 corresponding to the intermediate height, so that the first pinning point PP1 and the second pinning point PP2 may be appropriately and/or readily separated in the manufacturing process (e.g., the manufacturing process of the light emitting element EL) of the display panel 100.

In an embodiment, the first electrode ET1 may be the anode electrode of the light emitting element EL, and the first intermediate layer IL1 may include at least one of the hole injection layer HIL or the hole transport layer HTL. For example, the first intermediate layer IL1 may be formed as the hole injection layer HIL as shown in FIG. 5. As another example, the first intermediate layer IL1 may include the hole injection layer HIL and the hole transport layer HTL that are sequentially disposed on the first electrode ET1 as shown in FIG. 6.

In an embodiment, the first intermediate layer IL1 may include an organic material. For example, each of the hole injection layer HIL and the hole transport layer HTL may include an organic material. However, embodiments are not limited thereto. For example, at least one of the hole injection layer HIL or the hole transport layer HTL may include an inorganic material. The structure and/or material of the first intermediate layer IL1 may change depending on embodiments.

The hole injection layer HIL may be positioned between the first electrode ET1 and the light emitting layer EML (or between the first electrode ET1 and the hole transport layer HTL). In an embodiment, the hole injection layer HIL may include a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino]triphenylamine (m-MTDATA), 4,4′4″-Tris (N,N-diphenylamino) triphenylamine (TDATA), 4,4′, 4″-tris {N,-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate) (PANI/PSS), NPD(N,N′-di(naphthalene-1-yl)-N,N′-diphenyl-benzidine), polyether ketone (TPAPEK) containing triphenylamine, 4-Isopropyl-4′-methyldiphenyliodonium [Tetrakis (pentafluorophenyl)borate], or HAT-CN(dipyrazino [2,3-f: 2′,3′-h] quinoxaline-2,3,6,7,10,11-hexacarbonitrile). The hole injection layer HIL may include materials other than the materials described herein.

The hole transport layer HTL may be positioned between the hole injection layer HIL and the light emitting layer EML (or between the first electrode ET1 and the light emitting layer EML).

In an embodiment, the hole transport layer HTL may include a carbazole-based derivative such as N-phenylcarbazole and polyvinylcarbazole, a fluorene-based derivative, a triphenylamine-based derivative such as TPD(N,N′-bis(3-methylphenyl)-N,N′-diphenyl-[1,1-biphenyl]-4,4′-diamine) and TCTA(4,4′,4″-tris(N-carbazolyl)triphenylamine), NPD(N,N′-di(naphthalene-1-yl)-N,N′-diphenyl-benzidine), TAPC(4,4′-Cyclohexylidene bis[N,N-bis(4-methylphenyl)benzenamine]), HMTPD(4,4′-Bis [N,N′-(3-tolyl)amino]-3,3′-dimethylbiphenyl), or mCP(1,3-Bis (N-carbazolyl)benzene). The hole transport layer HTL may include materials other than the materials described herein.

In an embodiment, the first intermediate layer IL1 may be formed by an inkjet printing process. For example, each of the hole injection layer HIL and the hole transport layer HTL may be formed by applying a solution in which a material to be used for forming the hole injection layer HIL or the hole transport layer HTL is dispersed in a solvent containing an organic material to each emission area EA using a method such as an inkjet printing process or the like and by volatilizing the solvent. In an embodiment, the first intermediate layer IL1 may further include an additive for dispersion stability of the material dispersed in the solvent. However, the method for forming the first intermediate layer IL1 is not limited thereto. For example, the first intermediate layer IL1 may be formed using another method such as a vacuum deposition method, a spin coating method, a casting method, a Langmuir-Blodgett (LB) method, a laser printing method, a laser induced thermal imaging (LITI) method, or the like.

In embodiments, the first intermediate layer IL1 may be formed up to the middle of the bank BNK. For example, the first intermediate layer IL1 may be formed to the first height h1 lower than the height of the bank BNK. For example, the maximum height of the first intermediate layer IL1 with respect to the top surface of the first electrode ET1 may be the first height h1. The first height h1 may be a height with respect to the bottom surface (or the top surface of the fourth insulating layer 150) of the bank BNK, but is not limited thereto. For example, the first height h1 may be defined with respect to the top surface of the first electrode ET1.

In an embodiment, the central portion of the first intermediate layer IL1 may be formed at a height lower than the first height h1, and may be substantially flat. The height of the edge portion of the first intermediate layer IL1 may gradually increase toward the bank BNK. A top surface S1 of the first intermediate layer IL1 may contact the side surface of the bank BNK at the first pinning point PP1 of the first height h1. For example, the edge portion of the top surface S1 of the first intermediate layer IL1 may be disposed on the side surface of the bank BNK at the first pinning point PP1.

In an embodiment, the first height h1 may be higher than or equal to the third height h3, and the first pinning point PP1 may be positioned at the upper part BNP2 of the bank BNK. For example, a part (e.g., the upper part of the first intermediate layer IL1) of the first intermediate layer IL1 close to the first pinning point PP1 may be surrounded by the upper part BNP2 of the bank BNK, and the remaining portion of the first intermediate layer IL1 may be surrounded by the lower part BNP1 of the bank BNK.

The light emitting layer EML may be disposed on the first intermediate layer IL1. The light emitting layer EML may include a high molecular material or a low molecular material.

Light emitted from the light emitting layer EML may contribute to image display. In an embodiment, the light emitting layer EML may be provided for each pixel PX, and the light emitting layer of each pixel PX may emit visible light of a color corresponding to the corresponding pixel PX. In another embodiment, the light emitting layers EML of the pixels PX may emit light of the same specific color, and a wavelength conversion layer corresponding to the color (or the wavelength band) of the light to be emitted from the pixels PX may be disposed in the emission areas EA of at least some pixels PX.

In an embodiment, the light emitting layer EML may be a quantum dot light emitting layer including quantum dots QD. In this case, each light emitting element EL may be a quantum dot light emitting diode.

For example, the light emitting layer EML may include the quantum dot QD having a core-shell structure. In an embodiment, the core of the quantum dot QD may be selected from a group II-VI compound, a group III-V compound, a group IV-VI compound, a group IV element, a group IV compound, and combinations thereof.

The group II-VI compound may be selected from the group consisting of binary compounds, ternary compounds, and quaternary compounds. For example, the binary compounds may be selected from the group consisting of CdSe, CdTe, ZnS, ZnSe, ZnTe, ZnO, HgS, HgSe, HgTe, MgSe, MgS, and mixtures thereof, the ternary compounds may be selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof, and the quaternary compounds may be selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The group III-V compound may be selected from the group consisting of binary compounds, ternary compounds, and quaternary compounds. For example, the binary compounds may be selected from the group consisting of GaN, GaP, GaAs, GaSb, AlN, AlP, AlAs, AlSb, InN, InP, InAs, InSb, and mixtures thereof, the ternary compounds may be selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InPSb, GaAlNP, and mixtures thereof, and the quaternary compounds may be selected from the group consisting of GaAlNAs, GaAlNSb, GaAlPAs, GaAlPSb, GaInNP, GaInNAs, GaInNSb, GalnPAs, GaInPSb, InAlNP, InAlNAs, InAlNSb, InAlPAs, InAlPSb, and mixtures thereof.

The group IV-VI compound may be selected from the group consisting of binary compounds, ternary compounds, and quaternary compounds. For example, the binary compounds may be selected from the group consisting of SnS, SnSe, SnTe, PbS, PbSe, PbTe, and mixtures thereof, the ternary compounds may be selected from the group consisting of SnSeS, SnSeTe, SnSTe, PbSeS, PbSeTe, PbSTe, SnPbS, SnPbSe, SnPbTe, and mixtures thereof, and the quaternary compounds may be selected from the group consisting of SnPbSSe, SnPbSeTe, SnPbSTe, and mixtures thereof.

The group IV element may be selected from the group consisting of Si, Ge, and a mixture thereof.

The group IV compound may be a binary compound selected from the group consisting of SiC, SiGe, and a mixture thereof.

The binary compound, the tertiary compound, or the quaternary compound may exist in particles at a uniform concentration, or may exist in the same particle after divided into states where concentration distributions are partially different. Further, the particles may have a core-shell structure in which one quantum dot QD surrounds another quantum dot QD. An interface between the core and the shell may have a concentration gradient in which the concentration of elements present in the shell decreases toward the center.

In an embodiment, the quantum dot QD may have a core-shell structure including a core including a nanocrystal and a shell surrounding the core. The shell of the quantum dot QD may serve as a protective layer for maintaining semiconductor characteristics by preventing chemical denaturation of the core and/or as a charging layer for giving electrophoretic characteristics to the quantum dot QD. The shell may be a single layer or a multilayer. An interface between the core and the shell may have a concentration gradient in which the concentration of elements present in the shell decreases toward the center. Examples of the shell of the quantum dot QD may include a metal or non-metal oxide, a semiconductor compound, and a combination thereof. For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a tertiary compound such as MgAl₂O₄, CoFe₂O₄, NiFe₂O₄, and CoMn₂O₄, but the disclosure is not limited thereto. The semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, but the disclosure is not limited thereto.

The quantum dot QD may have a full width at half maximum (FWHM) of an emission wavelength spectrum of about 45 nm or less, preferably about 40 nm or less, more preferably about 30 nm or less, and color purity or color reproducibility may be improved in this range. Since the light emitted through the quantum dot QD is emitted in all directions, an optical viewing angle may be improved.

The type of the quantum dot QD is not particularly limited to one commonly used in the art, but more specifically, the quantum dot may have a spherical shape, a pyramidal shape, a multi-arm shape, or may be a cubic nanoparticle, a nanotube, a nanowire, a nanofiber, a nanoplate particle, or the like.

The quantum dot QD may control the color of emitted light depending on a particle size. Accordingly, the quantum dot QD may have various emission colors such as blue, red, and green.

In an embodiment, the first to third light emitting elements EL1, EL2, and EL3 may emit light of different colors and/or wavelengths depending on sizes or types of the quantum dots QD included in the respective light emitting layers EML. For example, the light emitting layer EML of the first light emitting element EL1 may emit red light, the light emitting layer EML of the second light emitting element EL2 may emit green light, and the light emitting layer EML of the third light emitting element EL3 may emit blue light.

In an embodiment, the light emitting layer EML of each of the first to third light emitting elements EL1, EL2, and EL3 may be formed by an inkjet printing process. For example, the light emitting layer EML of each of the first to third light emitting elements EL1, EL2, and EL3 may be formed by dispersing the quantum dots QD in a solvent, applying the solvent to each emission area EA using a method such as an inkjet printing process or the like, and volatilizing the solvent. However, the method for forming the light emitting layer EML is not limited thereto. For example, the light emitting layer EML may be formed using various methods such as a vacuum deposition method, a spin coating method, a casting method, an LB method, a laser printing method, and a laser induced thermal imaging method.

The light emitting layer EML according to embodiments is not limited to the quantum dot light emitting layer. For example, the light emitting layer EML may be an organic light emitting layer that does not include the quantum dot QD.

In embodiments, the light emitting layer EML may be formed to a second height h2 higher than the first height h1. For example, the maximum height of the light emitting layer EML with respect to the bottom surface (or the top surface of the fourth insulating layer 150) of the bank BNK may be the second height h2. In an embodiment, the light emitting layer EML may be formed at a height lower than or equal to the height of the bank BNK. For example, the second height h2 may be lower than or equal to the height of the bank BNK. In embodiments, the second height h2 may be a height with respect to the bottom surface (or the top surface of the fourth insulating layer 150) of the bank BNK, but is not limited thereto. For example, the second height h2 may be defined with respect to the top surface of the first electrode ET1.

In an embodiment, the central portion of the light emitting layer EML may be formed at a height lower than the second height h2, and may be substantially flat. The height of the edge portion of the light emitting layer EML may gradually increase toward the bank BNK. The top surface S2 of the light emitting layer EML may contact the side surface of the bank BNK at the second pinning point PP2 of the second height h2. For example, the edge portion of the top surface S2 of the light emitting layer EML may meet the bank BNK at the second pinning point PP2.

In embodiments, the side surface of the light emitting layer EML may contact the side surface of the bank BNK between the first pinning point PP1 and the second pinning point PP2. For example, the first pinning point PP1 and the second pinning point PP2 may be separated from each other with the light emitting layer EML interposed therebetween.

The second intermediate layer IL2 may be disposed on the light emitting layer EML. In an embodiment, the second electrode ET2 may be the cathode electrode of the light emitting element EL, and the second intermediate layer IL2 may include at least one electron transport layer ETL. For example, the second intermediate layer IL2 may be formed as a single electron transport layer ETL as shown in FIG. 5. As another example, the second intermediate layer IL2 may include a first electron transport layer ETL1 and a second electron transport layer ETL2 that are sequentially disposed on the light emitting layer EML as shown in FIG. 6.

In an embodiment, the second intermediate layer IL2 may include an inorganic material. For example, the electron transport layer ETL (or each of the first electron transport layer ETL1 and the second electron transport layer ETL2) may include an inorganic material. For example, the electron transport layer ETL may include a metal oxide containing at least one metal selected from an alkaline earth metal, a transition metal, a Group 13 metal, or a Group 14 metal, or another metal. The metal in the metal oxide may be, e.g., Zn, Ti, Zr, Sn, W, Ta, Ni, Mo, Cu, Mg, Co, Mn, Y, Al, or any combination thereof, but embodiments are not limited thereto.

In an embodiment, the second intermediate layer IL2 may include zinc oxide. The type of zinc oxide is not particularly limited, but may be, e.g., ZnO, Mg-doped ZnO (ZnMgO), or a combination thereof, and may be doped with Li and Y other than Mg. However, embodiments are not limited thereto. For example, the second intermediate layer IL2 may include zinc oxide.

In an embodiment, zinc oxide may be included in two or more layers included in the second intermediate layer IL2. For example, the first intermediate layer IL1 may have a multi-layer structure including the first electron transport layer ETL1 including ZnO and the second electron transport layer ETL2 including ZnMgO.

The second intermediate layer IL2 may include materials other than the materials described herein.

In an embodiment, the second intermediate layer IL2 may be formed by an inkjet printing process. For example, the electron transport layer ETL (or each of the first electron transport layer ETL1 and the second electron transport layer ETL2) may be formed by applying a solution in which a material (e.g., ZnO or another metal oxide) to be used for forming the electron transport layer ETL is dispersed in a solvent on each emission area EA using a method such as an inkjet printing process or the like, and by volatilizing the solvent. In an embodiment, the second intermediate layer IL2 may further include an additive for dispersion stability of the material (e.g., the metal oxide) dispersed in the solvent. However, the method for forming the second intermediate layer IL2 is not limited thereto. For example, the second intermediate layer IL2 may be formed using another method such as a vacuum deposition method, a spin coating method, a casting method, an LB method, a laser printing method, or a laser induced thermal imaging method.

The second intermediate layer IL2 may be formed at a height higher than or equal to the second height h2. In an embodiment, the second intermediate layer IL2 may be formed at a height lower than or equal to the height of the bank BNK. For example, the second intermediate layer IL2 may be formed at the second height h2, similar to the light emitting layer EML. For example, the maximum height of the second intermediate layer IL2 with respect to the bottom surface (or the top surface of the fourth insulating layer 150) of the bank BNK may be the second height h2.

In an embodiment, the central portion of the second intermediate layer IL2 may be formed at a height lower than the second height h2, and may be substantially flat. The height of the edge portion of the second intermediate layer IL2 may gradually increase toward the bank BNK. A top surface S3 of the second intermediate layer IL2 may contact the side surface of the bank BNK at the second pinning point PP2 of the second height h2. For example, the edge portion of the top surface S3 of the second intermediate layer IL2 may meet the bank BNK at the second pinning point PP2.

In an embodiment, the first intermediate layer IL1 and the second intermediate layer IL2 may be appropriately and/or readily separated by adjusting surface energy of an ink used for forming the first intermediate layer IL1, the light emitting layer EML, and the second intermediate layer IL2 of the light emitting element EL. For example, by forming the light emitting layer EML using the ink having the surface energy higher than the surface energy of the ink used for forming the first intermediate layer IL1, the first intermediate layer IL1 and the light emitting layer EML may be formed such that the first pinning point PP1 and the second pinning point PP2 are appropriately separated. In an embodiment, the second intermediate layer IL2 may be formed using the ink having the surface energy that is substantially the same as or similar to the surface energy of the ink used for forming the light emitting layer EML, and the light emitting layer EML and the pinning point (e.g., the second pinning point PP2) of the second intermediate layer IL2 may meet each other on the side surface of the bank BNK. For example, the top surface S2 of the light emitting layer EML and the top surface S3 of the second intermediate layer IL2 may contact the side surface of the bank BNK at the second pinning point PP2 of the second height h2.

In embodiments, the first pinning point PP1 of the first intermediate layer IL1 and the second pinning point PP2 of the light emitting layer EML and the second intermediate layer IL2 may be formed separately at different heights, so that the level difference formed at the top surface S3 of the second intermediate layer IL2 may be reduced. For example, the height difference between the central portion and the edge portion of the second intermediate layer IL2 may be smaller than the height difference between the central portion and the edge portion of the first intermediate layer IL1. Further, the inclination angle of the edge portion of the top surface S3 of the second intermediate layer IL2 may be smaller than the inclination angle of the edge portion of the top surface S1 of the first intermediate layer IL1. For example, the second intermediate layer IL2 may include an inclined surface formed at the edge portion close to the bank BNK and having an inclination angle smaller than the inclination angle of an inclined surface formed at the edge portion of the first intermediate layer IL1.

In an embodiment, the first intermediate layer IL1 and the second intermediate layer IL2 may be completely separated with the light emitting layer EML interposed therebetween. For example, the first intermediate layer IL1 and the second intermediate layer IL2 may not meet each other even on the side surface of the bank BNK. Accordingly, a leakage current (e.g., lateral leakage) through the side surface of the light emitting element EL may be blocked, and characteristics (e.g., luminance efficiency and/or reliability) of the light emitting element EL and the pixel PX including the same may be improved.

Since the top surface S3 of the second intermediate layer IL2 is formed to be relatively gentle, disconnection of the second electrode ET2 disposed on the second intermediate layer IL2 may be prevented. For example, since the top surface S3 of the second intermediate layer IL2 has a gentle shape, even if the thin second electrode ET2 is formed on the second intermediate layer IL2, the second electrode ET2 may be stably connected without disconnection.

The second electrode ET2 may be disposed on the second intermediate layer IL2. In an embodiment, the second electrode ET2 may be a common electrode shared by the light emitting elements EL of the pixels PX. For example, the second electrode ET2 may be disposed on the second intermediate layer IL2 and the bank BNK, and may be entirely disposed in the display area DA where the pixels PX are arranged.

In an embodiment, the second electrode ET2 may be substantially transparent or translucent. For example, the second electrode ET2 may include a transparent electrode layer including ITO, IZO, ITZO, AZO, or another transparent conductive material. As another example, the second electrode ET2 may include a translucent electrode layer made of Li, Ca, LiF/Ca, LiF/Al, Al, Mg, or a compound thereof. For example, the second electrode ET2 may be formed as a translucent electrode made of silver (Ag) and magnesium (Mg).

In an embodiment, the second electrode ET2 may have a limited thickness, so that it is possible to increase the light transmittance of the second electrode ET2 and improve the light efficiency of the pixel PX. For example, the second electrode ET2 may have a thickness of about 90 Å or less, so that the light efficiency of the pixel PX may be improved or optimized.

The encapsulation layer ENL may be disposed on the light emitting element layer ELL. In an embodiment, the encapsulation layer ENL may include at least one inorganic layer and at least one organic layer in order to protect the light emitting elements EL from permeation of oxygen or moisture or foreign substances such as dust. For example, the encapsulation layer ENL may be formed to have a structure in which a first encapsulation layer 171, a second encapsulation layer 173, and a third encapsulation layer 175 are sequentially stacked each other. In an embodiment, the first encapsulation layer 171 and the third encapsulation layer 175 may include silicon nitride, silicon oxynitride, silicon oxide, titanium oxide, aluminum oxide, or other inorganic materials. In an embodiment, the second encapsulation layer 173 may include acryl resin, epoxy resin, phenolic resin, polyamide resin, polyimide resin, or other organic materials.

Although FIG. 4 illustrates an embodiment in which the light emitting element layer ELL is encapsulated by the encapsulation layer ENL, embodiments are not limited thereto. For example, the light emitting element layer ELL or the like may be encapsulated using a separate upper substrate.

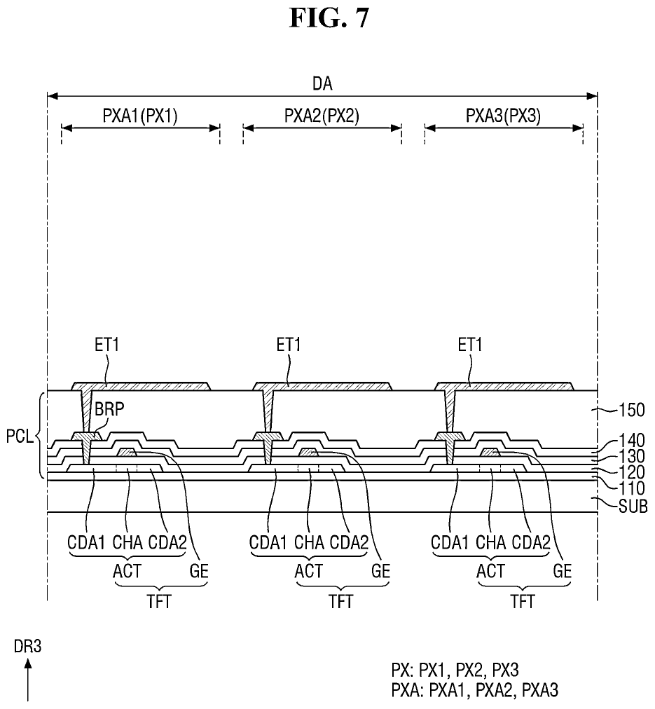

FIGS. 7 to 12 are schematic cross-sectional views illustrating a method for manufacturing the display device according to an embodiment. For example, FIGS. 7 to 12 sequentially illustrate steps of forming the light emitting element layer ELL on the substrate SUB and the panel circuit layer PCL among the steps of manufacturing the display panel 100 of FIG. 4.

Referring to FIG. 7, the first electrode ET1 of each of the light emitting elements EL may be formed on the substrate SUB. In an embodiment, the substrate SUB may include the display area DA including the pixel areas PXA (e.g., the first pixel area PXA1, the second pixel area PXA2, and the third pixel area PXA3), and the panel circuit layer PCL may be formed first on the substrate SUB. The first electrode ET1 may be formed in each pixel area PXA on the substrate SUB on which the panel circuit layer PCL is formed. The first electrode ET1 may be formed as a single layer or multiple layers using at least one conductive material.

In an embodiment, the first electrode ET1 may be made of the material described herein, and may be formed as multiple layers including the reflective electrode layer. For example, the first electrode ET1 may be formed to have a multi-layer structure such as ITO/Ag/ITO. However, the material and structure of the first electrode ET1 may variously change depending on embodiments.

In an embodiment, the first electrode ET1 may be formed by a film forming process (e.g., a deposition process) of a conductive film and a patterning process (e.g., an etching process using a mask) of the conductive film. However, the formation method of the first electrode ET1 may variously change depending on embodiments.

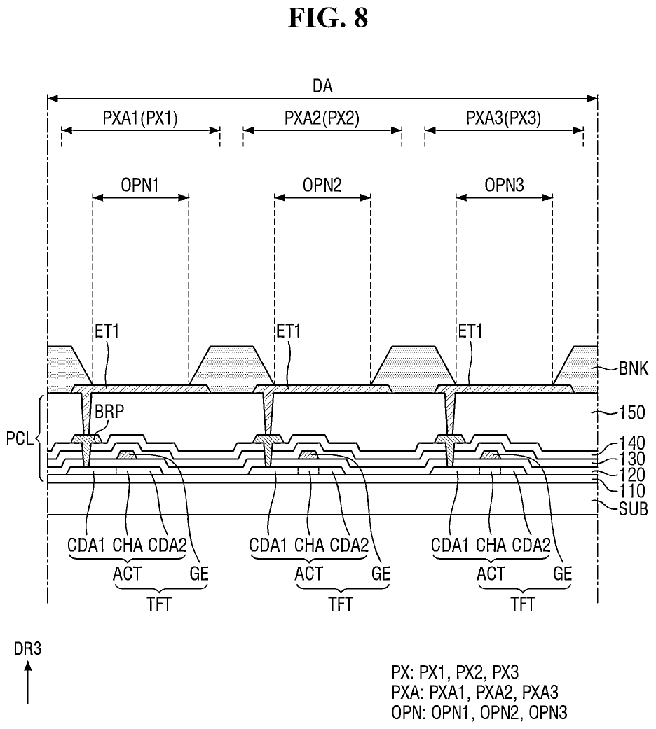

Referring to FIG. 8, the bank BNK may be formed on the substrate SUB on which the first electrode ET1 and the like are formed. The bank BNK may include the openings OPN for partitioning or defining the emission areas EA of the pixels PX. For example, the bank BNK may be opened to include the first opening OPN1, the second opening OPN2, and the third opening OPN3 in the first pixel area PXA1, the second pixel area PXA2, and the third pixel area PXA3, respectively. The bank BNK may cover the edge of the first electrode ET1 disposed in each pixel area PXA, and may expose the remaining portion of the first electrode ET1.

The bank BNK may be formed using the material described herein (e.g., an organic or inorganic insulating material), and may be formed as a single layer or multiple layers. The material, structure, and/or formation method of the bank BNK may variously change depending on embodiments.

In an embodiment, the bank BNK may be formed of a material containing fluorine (F). Further, the bank BNK may be formed to have higher liquid repellency at the upper part (e.g., the upper part BNP2 with a height higher than or equal to the third height h3 of FIG. 5 or 6) than at the lower part (e.g., the lower part BNP1 with a height lower than or equal to the third height h3 of FIG. 5 or 6) thereunder. The lower part BNP1 of the bank BNK may surround at least a part of the first intermediate layer IL1 to be formed in a subsequent process, and the upper part BNP2 of the bank BNK may surround the light emitting layer EML and the second intermediate layer IL2 to be formed in a subsequent process. In an embodiment, the surface characteristics of the bank BNK may be adjusted by adjusting or changing at least one of the material or the process condition of the bank BNK. For example, the bank BNK may be formed to contain fluorine (F) in the surface with a height higher than or equal to the third height h3 by adjusting at least one of the content of fluorine (F) and/or the material used for forming the bank BNK, or the process condition (e.g., baking temperature and/or time) of the bank BNK.

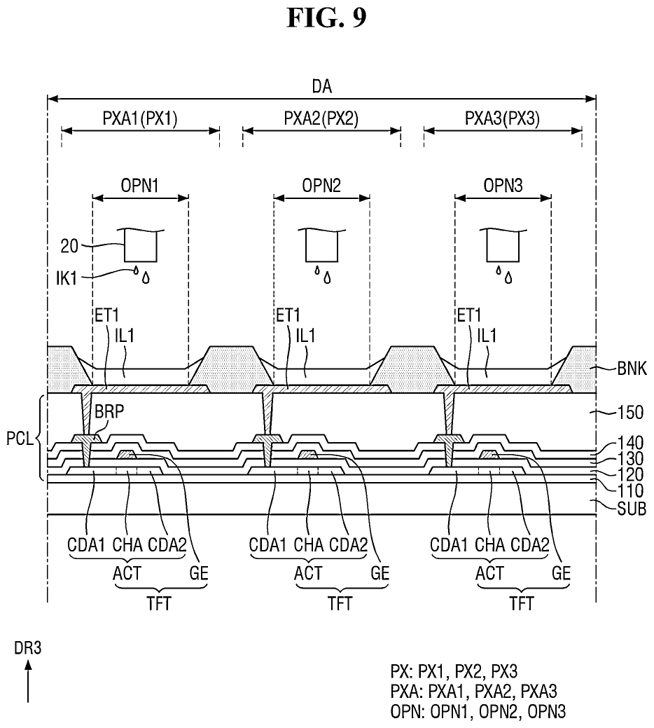

Referring to FIG. 9, the first intermediate layer IL1 may be formed on each first electrode ET1. The first intermediate layer IL1 may be formed on the exposed portion of the first electrode ET1 that is not covered by the bank BNK. In an embodiment, the first intermediate layer IL1 may be formed by an inkjet printing method using a first ink IK1 containing a material for forming the first intermediate layer IL1. For example, the first ink IK1 may be supplied to each pixel area PXA by an inkjet printing process using an inkjet printing equipment 20, and the first intermediate layer IL1 may be formed using a material contained in the first ink IK1. For example, the first intermediate layer IL1 may be formed by supplying the first ink IK1 onto the exposed portion of the first electrode ET1 and drying it by an inkjet printing method.

In an embodiment, in case that the first intermediate layer IL1 includes layers, the layers may be sequentially formed on the first electrode ET1. For example, in the case of forming the first intermediate layer IL1 including the hole injection layer HIL and the hole transport layer HTL as in the embodiment of FIG. 6, the hole injection layer HIL and the hole transport layer HTL may be sequentially formed on the first electrode ET1.

In an embodiment, the surface energy of the first ink IK1 may be adjusted by adjusting or changing the solvent of the first ink IK1. For example, the first ink IK1 may be manufactured to have a relatively high contact angle (e.g., a contact angle of about 40° or more) and relatively low surface energy.

In embodiments, the first intermediate layer IL1 may be formed to have the first pinning point PP1 in the middle of the bank BNK. For example, the first intermediate layer IL1 may be formed at a height lower than or equal to the first height h1 to have the first pinning point PP1 at the first height h1 belonging to the intermediate height of the bank BNK. The top surface S1 (see FIG. 5 or 6) of the first intermediate layer IL1 may contact the side surface of the bank BNK at the first pinning point PP1.

In an embodiment, the first intermediate layer IL1 may be substantially formed at a height lower than or equal to the third height h3, and the first pinning point PP1 of the first intermediate layer IL1 may be positioned at a height higher than or equal to the third height h3. For example, the first pinning point PP1 may be formed at the first height h1 close to the third height h3 and higher than the third height h3.

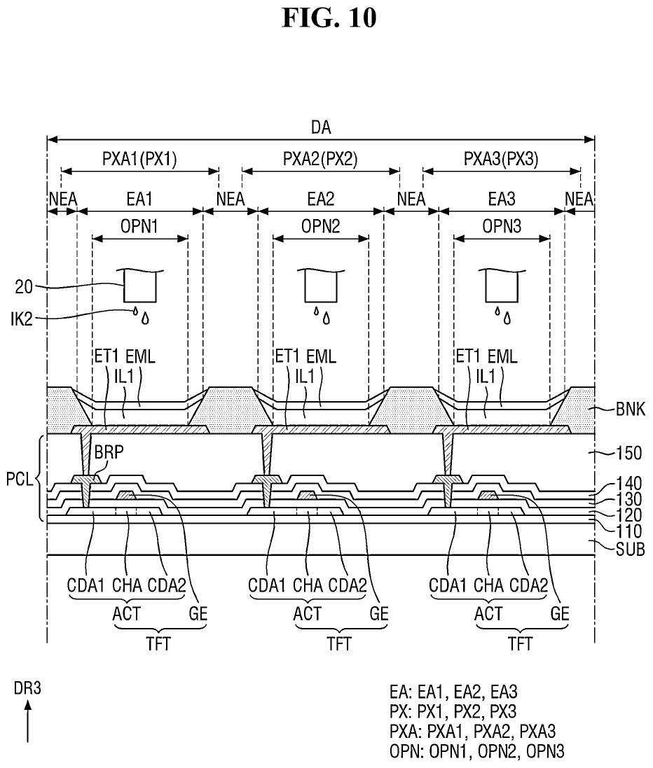

Referring to FIG. 10, the light emitting layer EML may be formed on each first intermediate layer IL1. In an embodiment, the light emitting layer EML may be formed by an inkjet printing method using a second ink IK2 containing a material for forming the light emitting layer EML. For example, the second ink IK2 may be supplied onto each first intermediate layer IL1 by an inkjet printing process using the inkjet printing equipment 20, and the light emitting layer EML may be formed using the material contained in the second ink IK2. For example, the light emitting layer EML may be formed by supplying the second ink IK2 onto the first intermediate layer IL1 and drying it using an inkjet printing method. In an embodiment, in case that the light emitting layer EML includes the quantum dot QD, the second ink IK2 may include the quantum dot QD.

In an embodiment, the surface energy of the second ink IK2 may be adjusted by adjusting or changing the solvent of the second ink IK2 or the ligand of the quantum dot QD. For example, the second ink IK2 may be manufactured to have a relatively low contact angle (e.g., a contact angle of about 20° or less) and relatively high surface energy compared to the first ink IK1. Accordingly, the first pinning point PP1 of the first intermediate layer IL1 and the second pinning point PP2 of the light emitting layer EML may be appropriately and/or readily separated. For example, the light emitting layer EML may be formed at a height lower than or equal to the second height h2 to thus have the second pinning point PP2 at the second height h2 higher than the first height h1. The top surface S2 (see FIG. 5 or 6) of the light emitting layer EML may contact the side surface of the bank BNK at the second pinning point

PP2. The side surface of the light emitting layer EML may contact the side surface of the bank BNK between the first pinning point PP1 and the second pinning point PP2.

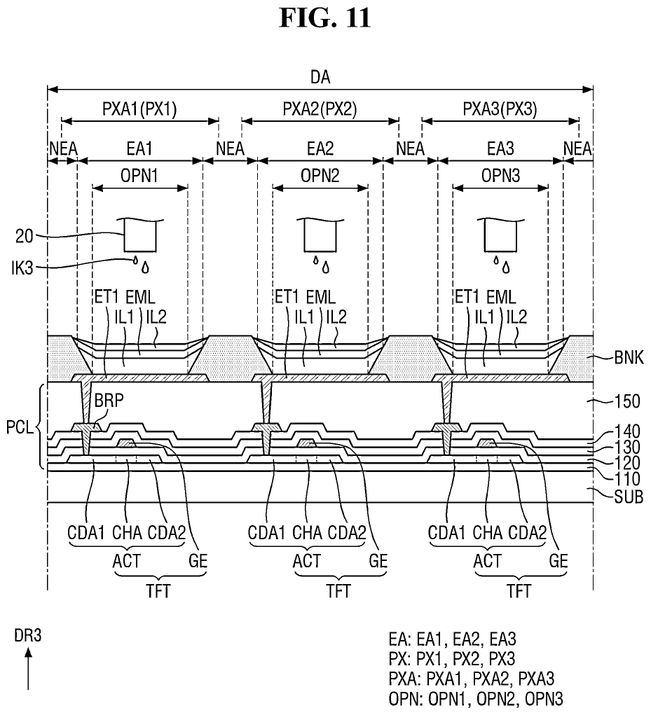

Referring to FIG. 11, the second intermediate layer IL2 may be formed on each light emitting layer EML. In an embodiment, the second intermediate layer IL2 may be formed by an inkjet printing method using a third ink IK3 containing a material for forming the second intermediate layer IL2. For example, the third ink IK3 may be supplied onto each light emitting layer EML by an inkjet printing process using the inkjet printing equipment 20, and the second intermediate layer IL2 may be formed using a material contained in the third ink IK3. For example, the second intermediate layer IL2 may be formed by supplying the third ink IK3 onto the light emitting layer EML and drying it using an inkjet printing method.

In an embodiment, in case that the second intermediate layer IL2 includes layers, the layers may be sequentially formed on the light emitting layer EML. For example, in the case of forming the second intermediate layer IL2 including the first electron transport layer ETL1 and the second electron transport layer ETL2 as in the embodiment of FIG. 6, the first electron transport layer ETL1 and the second electron transport layer ETL2 may be sequentially formed on the light emitting layer EML.

In an embodiment, the surface energy of the third ink IK3 may be adjusted by adjusting or changing the solvent of the third ink IK3. For example, the third ink IK3 may be manufactured to have a relatively low contact angle (e.g., a contact angle of about 20° or less) and relatively high surface energy compared to the first ink IK1. In an embodiment, the third ink IK3 may be manufactured to have surface energy that is substantially the same as or similar to that of the second ink IK2. Accordingly, the top surfaces S2 and S3 (see FIG. 5 or 6) of the light emitting layer EML and the second intermediate layer IL2 may meet each other at or around the second pinning point PP2. For example, the top surface S3 (see FIG. 5 or FIG. 6) of the second intermediate layer IL2 may contact the side surface of the bank BNK at the second pinning point PP2.

In case that the light emitting layer EML and the second intermediate layer IL2 are formed at a height lower than or equal to the second height h2 lower than or equal to the height of the bank BNK, it is possible to prevent the light emitting layer EML and the second intermediate layer IL2 from being formed thick at the edge portion of the emission area EA, thereby preventing the reduction of the effective light emitting area. Further, the second electrode ET2 may be formed more stably in a subsequent process by reducing the level difference caused by the bank BNK and the second intermediate layer IL2.

In an embodiment, the thickness of at least one of the first intermediate layer IL1, the light emitting layer EML, or the second intermediate layer IL2 of the light emitting element EL may be appropriately adjusted in consideration of the resonance distance of light emitted from each light emitting layer EML, thereby improving the emission quality. For example, the thickness of at least one of the first intermediate layer IL1, the light emitting layer EML, or the second intermediate layer IL2 formed in each of the first emission area EA1, the second emission area EA2, and the third emission area EA3 may be set differentially in consideration of the optical resonance distance corresponding to the first color light (e.g., red light) emitted from the light emitting layer EML formed in the first emission area EA1, the optical resonance distance corresponding to the second color light (e.g., green light) emitted from the light emitting layer EML formed in the second emission area EA2, and the optical resonance distance corresponding to the third color light (e.g., blue light) emitted from the light emitting layer EML formed in the third emission area EA3, so that the amount of ink (e.g., at least one of the first ink IK1, the second ink IK2, or the third ink IK3) supplied to each emission area EA may be adjusted.

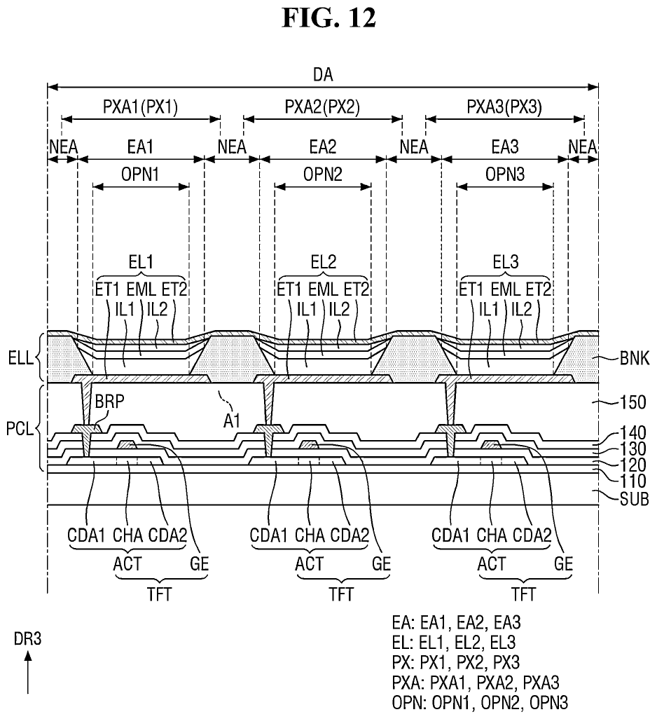

Referring to FIG. 12, the second electrode ET2 may be formed on each second intermediate layer IL2. In an embodiment, the second electrode ET2 may be formed entirely in the display area DA including the emission areas EA. For example, the second electrode ET2 may be formed on the bank BNK and the second intermediate layers IL2 of the light emitting elements EL.

In an embodiment, the second electrode ET2 may be formed using the material described herein. For example, the second electrode ET2 may be formed as a translucent electrode made of silver (Ag) and magnesium (Mg). In an embodiment, the second electrode ET2 may be formed to have a limited thickness (e.g., a thickness of about 90 Å or less) in order to improve or secure the light transmittance. However, the material, structure, and/or thickness of the second electrode ET2 may variously change depending on embodiments.

In accordance with embodiments, the level difference formed on the top surface of the bank BNK and/or the second intermediate layer IL2 may not be large, so that the disconnection of the second electrode ET2 may be prevented even if the second electrode ET2 is formed to have a thin thickness. Accordingly, the reliability of the light emitting element EL and the pixel PX including the same may be improved.

Since the second electrode ET2 is formed on the second intermediate layer IL2, the light emitting element EL may be formed in each emission area EA. Accordingly, the light emitting element layer ELL of the display panel 100 may be formed.

In an embodiment, in the case of manufacturing the display panel 100 including the encapsulation layer ENL as shown in FIG. 4, the encapsulation layer ENL may be additionally formed on the light emitting element layer ELL. For example, the first encapsulation layer 171, the second encapsulation layer 173, and the third encapsulation layer 175 may be sequentially formed on the light emitting element layer ELL. Accordingly, the display panel 100 according to an embodiment may be manufactured.

As described above, in the light emitting element EL according to embodiments, the first pinning point PP1 of the first intermediate layer ILL disposed on the first electrode ET1 may be disposed at the first height h1 positioned in the middle of the bank BNK, and the second pinning point PP2 of the light emitting layer EML and/or the second intermediate layer IL2 disposed on the first intermediate layer IL1 may be disposed at the second height h2 higher than the first height h1. Further, the first pinning point PP1 and the second pinning point PP2 may be spaced apart from each other, and the first intermediate layer IL1 and the second intermediate layer IL2 may not meet each other even at the edge portion adjacent to the side surface of the bank BNK.

In some embodiments, by controlling at least one of the taper angle θ of the bank BNK, the liquid repellency of the bank BNK, or the surface energy of the ink (e.g., the first ink IK1, the second ink IK2, and/or the third ink IK3) used for forming the light emitting element EL, the first pinning point PP1 and the second pinning point PP2 may be appropriately and/or readily separated. For example, by controlling at least one of the taper angle θ of the bank BNK, the liquid repellency of the bank BNK, or the surface energy of the ink used for forming the light emitting element EL, the first pinning point PP1 and the second pinning point PP2 may be appropriately and/or readily separated without forming a level difference at the side surface of the bank BNK.

In an embodiment, the bank BNK may have a taper angle θ of about 70° or more. For example, the side surface of the bank BNK may be formed as an inclined surface inclined at an angle θ of about 70° or more with respect to the top surface of the first electrode ET1.

In an embodiment, the bank BNK may have higher liquid repellency at the upper part BNP2 mainly surrounding the light emitting layer EML and the second intermediate layer IL2, than at the lower part BNP1 thereunder. For example, the bank BNK may include fluorine (F) (e.g., fluorine (F) with a value greater than or equal to the reference value) contained in the surface at the upper part BNP2 positioned at a height higher than or equal to the third height h3.

In an embodiment, the second ink IK2 applied to the emission area EA to form the light emitting layer EML may have surface energy higher than the surface energy of the first ink IK1 applied to the emission area EA to form the first intermediate layer IL1. In an embodiment, the third ink IK3 applied to the emission area EA to form the second intermediate layer IL2 may have surface energy higher than the surface energy of the first ink IK1. For example, the surface energy of the second ink IK2 and the surface energy of the third ink IK3 may be substantially the same or similar.

In accordance with embodiments, the opening ratio and the light emitting area of the pixel PX may be improved or secured by forming the taper angle θ of the bank BNK to be about 70° or more. For example, by forming the taper angle θ of the bank BNK to be about 70° or more, the area of each of the openings OPN formed in the bank BNK may be increased and, accordingly, the area (e.g., the light emitting area) of the emission area EA where the light emitting layer EML of the light emitting element EL is formed may increase. Accordingly, the luminance of the pixel PX may be improved or secured. Further, since the opening ratio and the light emitting area of the pixel PX are improved, the high-resolution display panel 100 (or the high-resolution display device 10 including the display panel 100) may be appropriately and/or readily manufactured.

Further, in accordance with embodiments, the first intermediate layer IL1 and the second intermediate layer IL2 of the light emitting element EL may be stably separated and/or spaced apart from each other with the light emitting layer EML interposed therebetween, so that the leakage current may be blocked. For example, the lateral leakage that may occur on the side surface of the light emitting element EL may be effectively blocked. Further, since the first pinning point PP1 and the second pinning point PP2 are stably separated and/or spaced apart from each other, the level difference on the top surface of the second intermediate layer IL2 may be reduced. Accordingly, the second electrode ET2 may be stably formed on the second intermediate layer IL2 and the bank BNK. For example, even if the second electrode ET2 is formed to have a small thickness of about 90 Å or less, the disconnection of the second electrode ET2 may be prevented.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a light emitting element disposed in an emission area; and
a bank surrounding the emission area, wherein
the light emitting element comprises:
a first electrode;
a first intermediate layer disposed on the first electrode, having a first height lower than a height of the bank, and surrounded by the bank;
a light emitting layer disposed on the first intermediate layer, having a second height higher than the first height, and surrounded by the bank;
a second intermediate layer disposed on the light emitting layer, having the second height, and surrounded by the bank; and
a second electrode disposed on the second intermediate layer,
a top surface of the first intermediate layer is in contact with a side surface of the bank at a first pinning point of the first height, and
top surfaces of the light emitting layer and the second intermediate layer are in contact with the side surface of the bank at a second pinning point of the second height.

2. The display device of claim 1, wherein a side surface of the light emitting layer is in contact with the side surface of the bank between the first pinning point and the second pinning point.

3. The display device of claim 1, wherein the bank comprises:
a lower part surrounding the first intermediate layer; and
an upper part surrounding the light emitting layer and the second intermediate layer and having higher liquid repellency than the lower part.

4. The display device of claim 3, wherein the bank contains fluorine contained in a surface at a height higher than or equal to a third height lower than a height of a top surface of the bank.

5. The display device of claim 1, wherein the height of the bank is higher than or equal to the second height.

6. The display device of claim 1, wherein the bank covers an edge portion of the first electrode, and exposes a remaining area comprising a central portion of the first electrode, and
the side surface of the bank is inclined at an angle of about 70° or more with respect to a top surface of the first electrode.

7. The display device of claim 1, wherein
the first intermediate layer comprises at least one of a hole injection layer or a hole transport layer, and
the second intermediate layer comprises an electron transport layer.

8. The display device of claim 1, wherein the light emitting layer comprises a quantum dot.

9. The display device of claim 1, wherein the second electrode is disposed on the second intermediate layer and the bank, and is entirely disposed in a display area comprising a plurality of emission areas comprising the emission area.

10. The display device of claim 1, wherein the second electrode has a thickness of about 90 Å or less.

11. A display device comprising:
a light emitting element disposed in an emission area; and
a bank surrounding the emission area, wherein
the light emitting element comprises:
a first electrode;
a first intermediate layer disposed on the first electrode, having a first height lower than a height of the bank, and surrounded by the bank;
a light emitting layer disposed on the first intermediate layer, having a second height higher than the first height, and surrounded by the bank;
a second intermediate layer disposed on the light emitting layer, having a height higher than or equal to the second height, and surrounded by the bank; and
a second electrode disposed on the second intermediate layer, and
the bank comprises a lower part surrounding the first intermediate layer, and an upper part surrounding the light emitting layer and the second intermediate layer and having higher liquid repellency than the lower part.

12. The display device of claim 11, wherein the second intermediate layer is having the second height.

13. The display device of claim 12, wherein
a top surface of the first intermediate layer is in contact with a side surface of the bank at a first pinning point of the first height, and
top surfaces of the light emitting layer and the second intermediate layer are in contact with the side surface of the bank at a second pinning point of the second height.

14. The display device of claim 13, wherein a side surface of the light emitting layer is in contact with the side surface of the bank between the first pinning point and the second pinning point.

15. The display device of claim 11, wherein the bank contains fluorine contained in a surface at a height higher than or equal to a third height lower than a height of a top surface of the bank.

16. The display device of claim 11, wherein
the bank covers an edge portion of the first electrode, and exposes a remaining area comprising a central portion of the first electrode, and
a side surface of the bank is inclined at an angle of about 70° or more with respect to a top surface of the first electrode.

17. The display device of claim 11, wherein
the first intermediate layer comprises at least one of a hole injection layer or a hole transport layer, and
the second intermediate layer comprises an electron transport layer.

18. The display device of claim 11, wherein the light emitting layer comprises a quantum dot.

19. A method for manufacturing a display device, comprising:
forming a first electrode on a substrate;
forming a bank covering an edge of the first electrode, and exposing a remaining portion of the first electrode;
supplying a first ink onto the exposed portion of the first electrode, and forming a first intermediate layer using a material contained in the first ink;
supplying a second ink having surface energy higher than that of the first ink onto the first intermediate layer, and forming a light emitting layer using a material contained in the second ink;
supplying a third ink onto the light emitting layer, and forming a second intermediate layer using a material contained in the third ink; and
forming a second electrode on the second intermediate layer, wherein
a top surface of the first intermediate layer is formed to be in contact with a side surface of the bank at a first pinning point of a first height lower than a height of the bank, and
a top surface of the light emitting layer is formed to be in contact with the side surface of the bank at a second pinning point of a second height higher than the first height.

20. The method of claim 19, wherein the bank is formed of a material containing fluorine, and is formed to have higher liquid repellency at an upper part higher than or equal to a third height than at a lower part lower than or equal to the third height.
